(19) United States
(12) Patent Application Publication
(10) Pub. No.: US 2008/0136019 A1
(43) Pub. Date: Jun. 12, 2008

(54) Solder Bump/Under Bump Metallurgy Structure for High Temperature Applications

(76) Inventors: Michael E. Johnson, Tempe, AZ (US); Thomas Strothmann, Tucson, AZ (US); Joan Vrtis, Mesa, AZ (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 11/609,036

(22) Filed: Dec. 11, 2006

(51) Int. Cl. H01L 23/488

(52) U.S. Cl. 257/737; 257/E23.023

(57) ABSTRACT

Solder bump structures, which comprise a solder bump on a UBM structure, are provided for operation at temperatures of 250° C. and above. According to a first embodiment, the UBM structure comprises layers of Ni—P, Pd—P, and gold, wherein the Ni—P and Pd—P layers act as barrier and/or solderable/bondable layers. The gold layer acts as a protective layer. According to second embodiment, the UBM structure comprises layers of Ni—P and gold, wherein the Ni—P layer acts as a diffusion barrier as well as a solderable/bondable layer, and the gold acts as a protective layer. According to a third embodiment, the UBM structure comprises: (i) a thin layer of metal, such as titanium or aluminum or Ti/W alloy; (ii) a metal, such as NiV, W, Ti, Pt, TiW alloy or Ti/W/N alloy; and (iii) a metal alloy such as Pd—P, Ni—P, NiV, or TiW, followed by a layer of gold. Alternatively, a gold, silver, or palladium bump may be used instead of a solder bump in the UBM structure.

### BACKGROUND

1. Field of the Disclosure

The present disclosure relates generally to electronic product packaging, and more particularly to under bump metallurgy (UBM) structures on which solder or interconnect bumps are formed.

2. Background

Surface mount technology using solder bump array integrated circuit (IC) packages (e.g., flip chip assemblies, chip scale packages, and ball grid array structures) is well known in the semiconductor industry for simplifying the packaging and interconnection of ICs, as for example in ICs that include light emitting diodes (LEDs). Typically, a series of circular (as viewed from above, or semi-spherical in three dimensions) solder bumps are formed upon the surface of an IC package or other substrate in electrical contact with active or passive devices formed within or attached upon such substrate. Such solder bumps are then aligned with pads formed in a corresponding pattern upon a second substrate to which the first substrate is to be mounted. The aforementioned solder bumps are typically produced atop a semiconductor wafer (e.g., Si or GaAs), such as a silicon submount, or other substrate. Typically, an insulating or passivation layer is formed upon the upper surface of the wafer, and a series of exposed conductive pads (referred to as I/O pads) are accessible through vias formed within the passivation layer.

Each solder bump is typically formed atop one of the I/O pads, which typically are formed by aluminum metallization, though other metals such as copper, and in some cases gold, may be used. In forming the solder bump, typically a UBM structure is first formed atop the device metallization, and the solder bump is subsequently formed on top of the UBM structure.

The thermal performance of devices utilizing solder bumps may be limited by the thermal tolerance of the solder bump structure, which includes the solder bump and its associated UBM structure. More specifically, conventional solder bump structures are incapable of satisfactory operation at higher temperatures (e.g., near or above 250° C.), typically due to undesirable diffusion and/or other undesirable thermal performance in the solder bump structure.

Existing solder bump joints are not capable of withstanding the substantially higher operating temperatures typically found in higher-power devices due to inadequate thermal stability and/or performance. Furthermore, existing high-temperature solders may contain metals that are contaminants to other portions of the electronic device associated with the solder bump structure. For example, in LED devices, the diffusion of such contaminants may undesirably change the color of the emitted light.

Additionally, thermal instability in the solder bump structure may result from long term continuous use of a device, even at lower temperatures, depending on the materials used. Existing solder bump structures, even though considered thermally stable in lower-temperature operations, cannot be transferred to high temperature use due to a lack of adequate stability and/or performance at higher temperatures.

Accordingly, there is a need for an improved solder bump structure that is more thermally stable and better performing at higher operating temperatures, and that can be used in interconnect applications in electronic product packaging (e.g., LED IC packages) having operating temperatures of about 250° C. or higher.

### BRIEF DESCRIPTION OF THE DRAWINGS

For a more complete understanding of the present disclosure, reference is now made to the following figures, wherein like reference numbers refer to similar items throughout the figures:

FIGS. 1 to 5 illustrate UBM structures formed using plating.

FIGS. 6 to 9 illustrate UBM structures formed using sputter deposition and plating.

FIGS. 10 and 11 illustrate UBM structures formed via sputtering on the device metallization.

FIG. 12 illustrates a solder bump structure having a solder bump formed on a UBM structure.

The exemplification set out herein illustrates particular embodiments, and such exemplification is not intended to be construed as limiting in any manner.

### DETAILED DESCRIPTION

The following description and the drawings illustrate specific embodiments sufficiently to enable those skilled in the art to practice the structures and methods described herein. Other embodiments may incorporate structural, method, and other changes. Examples merely typify possible variations.

The present disclosure provides an interconnect bump structure having a solder bump (or a bump composed of a material other than solder as described below) formed on a supporting UBM structure. The interconnect or solder bump structure generally has improved thermal stability compared to prior solder bump structures, and can also be operated for longer periods of time at operating temperatures at or above 250° C., and more preferably above 300° C., as described below for several embodiments. The solder bump structure utilizes a multi-layered UBM structure that is preferably resistant to undesirable diffusion and protects the device metallization while providing a good adhesion/bonding between the solder and device metallization. In selecting materials for use in the various layers of the UBM structure, it is desirable that the materials selected provide one or more layers that are resistant to undesirable diffusion that could lead to defective interconnects.

In a first embodiment, the UBM structure comprises layers of Ni—P, Pd—P, and gold. The Ni—P and Pd—P layers act as a diffusion barrier and/or solderable/bondable layers. The overlying gold layer acts as a protective layer to prevent the underlying metal from oxidizing prior to the bump attach process.

In a second embodiment, the UBM structure comprises layers of Ni—P and gold. The Ni—P layer acts as a diffusion barrier and/or a solderable/bondable layer. The overlying gold layer acts as a protective layer.

In a third embodiment, the UBM structure comprises: (i) a thin layer of metal (e.g., titanium, aluminum, or Ti/W alloy) having good electrical conductivity and adhesion; (ii) a barrier metal layer (e.g., NiV, W, Ti, Pt, Ti/W alloy or Ti/W/N alloy), which acts as a barrier metal and is selected to be wettable with the selected solder alloy that will be used; and (iii) an additional metal layer (e.g., Pd—P, Ni—P, NiV, or Au) overlying the barrier metal layer. Alternatively, there may be a second additional layer of metal or alloy on top of the barrier metal layer. The second additional layer may be formed using one of the materials listed above for forming the barrier metal layer. An overlying gold layer acts as a protective layer.

The interconnect bump or solder bump formed on the UBM structure may be formed, for example, from one or more of the following materials: PbSbGa, PbSb, AuGe, AuSi, AuSn, ZnAl, CdAg, GeAl, Au, Ag, Pd, Pb, Ge, Sn, Si, Zn, Al, or a combination of the foregoing. As an alternative to a solder bump, in other embodiments a gold or silver bump may be placed on top of any of the UBM metals or alloys described herein that are compatible with the use of such gold or silver material.

It should be noted that, where described as solderable/bondable above, the layer(s) referred to are suitable for soldering, as well as wire bonding. These surfaces remain suitable for wire bonding even after the high temperature assembly of the soldered bumps.

### Formation of the UBM Structure

The UBM structure is typically formed atop the device, or silicon submount, or other substrate metallization, at the wafer level. The metallization of most devices is typically aluminum, though other metals such as copper, and less commonly gold, may also be used. The UBM structure may be multi-layered and may include individual adhesion layers, catalyst layers, barrier layers, solderable/bondable layers, surface protection layers, and/or layers having a combination of these properties.

The UBM structure may, for example, be formed by thin film metal sputtering methods or by immersion, electroless, or electrolytic plating methods, or by a combination of sputtering and plating. Although the specific embodiments described herein use plating and sputtering, other appropriate fabrication methods (e.g., evaporation, printing, etc.) for forming one or more of the layers in the UBM structure may be used.

### Forming a UBM Structure Using Plating

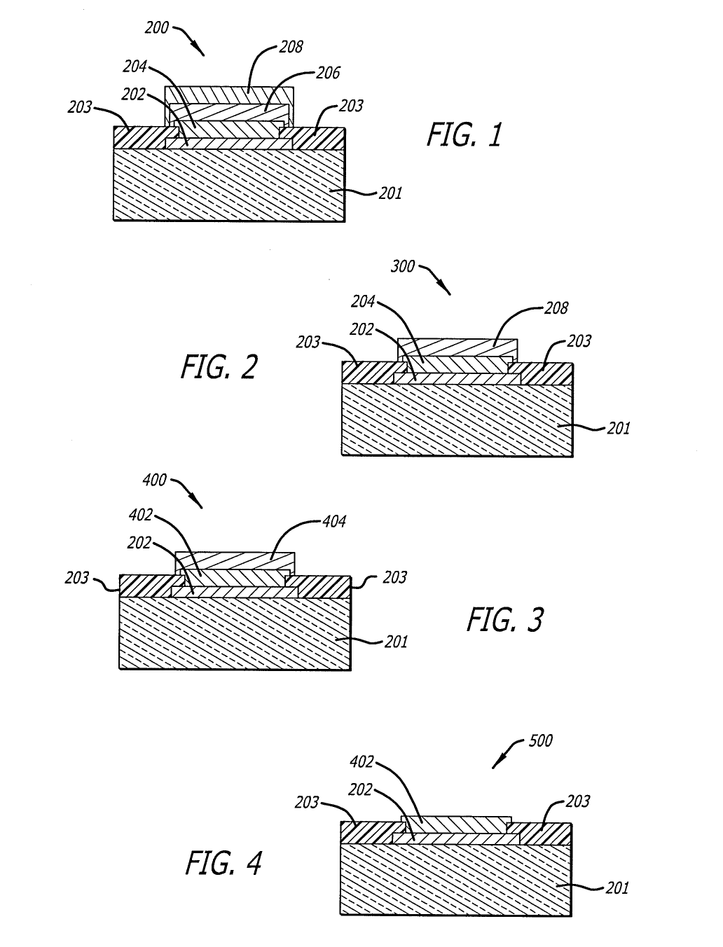

Five different, non-limiting examples are described below for forming a UBM structure using plating techniques. In each of the examples, a thin layer of catalyst is initially deposited on the surface of the device metallization via immersion plating. It should be noted that in FIGS. 1 to 5, the sacrificial metal and catalyst layer(s) of the UBM structure are not shown for simplicity of illustration. The examples presented below are prophetic examples.

### EXAMPLE 1

In reference to FIG. 1, the initial layer of the UBM structure 200 is formed on the metallization surface 202 of the device 201, which metallization surface is typically aluminum or copper. For purposes of illustration, a single I/O pad having a device metallization surface 202 with surrounding passivation layer 203 is shown.

The initial layer, which is a thin layer of a sacrificial metal or catalyst, is deposited onto metallization surface 202 via immersion plating. If the device has aluminum metallization, the metal deposited is zinc (a sacrificial metal layer). If the device metallization is copper, the metal deposited is palladium (a catalyst for further plating).

It should be noted that where it is mentioned in this disclosure that Pd is used as a catalyst, the Pd remains as a very thin layer within the final UBM structure. However, where it is mentioned in this disclosure that zinc is used as a sacrificial layer, the Zn layer substantially does not remain in the final UBM structure. Rather, the Zn is dissolved away and goes back into solution when the substrate/wafer goes into the electroless Ni plating bath, immediately before the nickel plating begins. The zinc layer is most appropriately described as a sacrificial layer having the purpose to protect the Al from oxidizing. Once the thin Zn layer is removed in the Ni bath, clean (un-oxidized) Al is exposed. Ni can plate on the clean Al, but not on oxidized Al.

Following the deposition of the metal catalyst or sacrificial layer, a layer 204 of a nickel-phosphorous (Ni—P) alloy containing P is formed. The alloy contains P in the range of about 1-16% by weight, and more preferably in the range of about 7-9%, and may be deposited via electroless plating methods. In some cases, the percentage of P in the alloy may be less than 1%. The thickness of the Ni—P deposit is in the 0.1-50 micron range, and more preferably in the range of 1-5 microns. Following the Ni—P deposit, a thin layer of palladium metal catalyst (not shown) is deposited via immersion plating methods.

Next, a layer 206 of palladium-phosphorous (Pd—P) alloy is formed. The alloy contains P in the range of about 0.1-10%, and more preferably in the range of about 0.1-5%, and may be deposited via electroless plating methods. The thickness of the Pd—P deposit is in the about 0.1-50 micron range, and more preferably in the range of about 0.1-5 microns. Layers 204 and 206 here provide a metal alloy stack.

Following the Pd—P deposit, a layer 208 of gold is plated via immersion plating methods. The thickness of the gold layer is in the 0.02-3.0 micron range, and more preferably in the range of 0.05-0.1 microns.

The Ni—P and Pd—P layers (204, 206) of the UBM structure 200 may act as either barrier or solderable/bondable layers, or these layers may provide a combination of these functions, depending on the thickness of the layers. The gold layer 208 acts as a protective or solderable/bondable layer depending on the thickness of the layer.

The catalyst layers (not shown) may be used to aid in the deposition of the respective subsequent layer, and though they are relatively thin, their specific thickness may vary depending on the deposition instruments, technique, process parameters, and quality of the materials used, which may vary depending on the equipment manufacturer. Alternatively, the above-described procedure may be carried out without deposition of the palladium metal catalyst after the Ni—P deposit because it may be possible to form a suitable Pd—P deposit layer directly on top of the Ni—P layer depending on the conditions and quality of materials used.

### EXAMPLE 2

A UBM structure 300, illustrated in FIG. 2, is formed according to the procedure described in Example 1, following the thin sacrificial or catalyst layer deposition, Ni—P deposition, and Au layer deposition steps, but omitting the Pd—P layer deposition step. As such, after deposition of the Ni—P layer 204, a layer of gold 208 is deposited via immersion plating methods. The thickness of the gold layer 208 is in the range of 0.02-3.0 microns, and more preferably in the range of 0.05-0.1 microns. In this embodiment, the Ni—P layer may act as a barrier or solderable/bondable layer, or provide a combination of these functions. The gold acts as a protective or solderable/bondable layer depending on the thickness of the layer.

### EXAMPLE 3

This example is only applicable to devices with Cu metallization. The UBM structure 400 illustrated in FIG. 3 is formed by first depositing a palladium metal catalyst upon the Cu surface (as for Example 1 above), then depositing a layer 402 of Pd—P with P in the range of 0.1-10% by weight, and more preferably in the range of 0.1-5%, via electroless plating methods. The thickness of the Pd—P layer 402 is in the range of 0.1-50 microns, and more preferably in the range of 0.1-5 microns.

Following deposition of the Pd—P layer, a layer 404 of gold is deposited using immersion plating methods. The thickness of this gold layer is in the range of 0.02-3 microns, and more preferably in the range of 0.05-0.1 microns. In this example, the Pd—P layer acts as a barrier and solderable/bondable layer. The Au layer acts as a protective layer.

### EXAMPLE 4

A UBM structure 500, illustrated in FIG. 4, is formed similarly as for Example 3 above. In this embodiment, no other layer is deposited upon the Pd—P layer 402. In this embodiment, the Pd—P layer acts as a barrier and solderable/bondable layer as Pd—P does not oxidize as readily as Ni—P.

### EXAMPLE 5

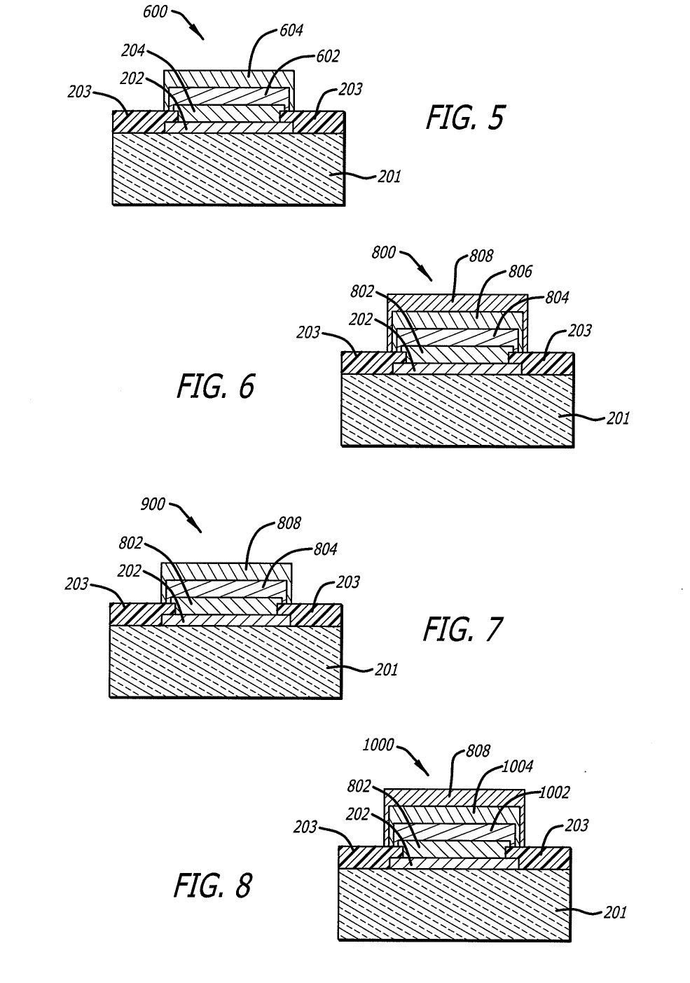

A UBM structure 600, illustrated in FIG. 5, is formed as for Example 1 above, then a second Ni—P layer 602 is deposited on top of the first Ni—P layer 204, via electroless plating methods. The second layer 602 of Ni—P has a percentage of P that is different than that of the first layer 204, and may be in the range of 1-16% by weight, but is more preferably in the range of 1-6%. The thickness of the second Ni—P layer 602 is in the range of 0.1-50 microns, and more preferably in the range of 1-5 microns. Following deposition of the second Ni—P layer 602, a layer of gold 604 is deposited via immersion plating methods. The thickness of this Au layer 604 is in the range of 0.02-3 microns, and more preferably in the range of 0.02-0.10 microns. In this embodiment the first Ni—P layer 204 acts as a barrier layer. The second Ni—P layer 602 acts as a barrier and solderable layer. The Au layer 604 acts as a protective layer.

### Forming a UBM Structure Using Sputter Deposition and Plating

A number of non-limiting examples are described below for forming a UBM structure using sputter deposition and plating techniques. In each of the examples, a thin layer of metal having good electrical conductivity and adhesion is initially deposited onto the surface of the device metallization via a sputter deposition process. Examples of such metals include titanium, aluminum, and a TiW alloy.

Next, a metal, which preferably acts as a barrier metal and is selected to be wettable with the selected solder alloy, may be deposited atop the thin layer of conductive metal. Examples of such metals include NiV, W, Ti, Pt, Ti/W alloy, and Ti/W/N alloy. In the case where a metal (e.g., NiV) oxidizes rapidly, a protective layer may optionally be deposited to prevent oxidation, then removed prior to deposition of the subsequent layer.

A metal alloy such as Pd—P, Ni—P, or NiV, or TiW may then be deposited upon the barrier metal. Prior to this deposition, a thin sacrificial or catalyst layer may optionally be deposited upon the barrier metal to aid deposition of the metal alloy, depending on the type of alloy used. Lastly, a gold or silver layer is deposited. It should be noted that some of the foregoing steps are omitted for certain of the examples below (e.g., Examples 10 and 17).

### EXAMPLE 6

A UBM structure 800, illustrated in FIG. 6, is formed by initially depositing a thin adhesion layer 802 of titanium metal via sputter deposition onto the surface of the device metallization 202. The device metallization 202 is typically aluminum, copper, or gold.

Next, a barrier layer 804 of nickel vanadium, which acts as a barrier metal, is sputtered onto the adhesion layer 802. However, the NiV layer 804 may oxidize rapidly upon exposure to atmosphere, thereby possibly making the material difficult to etch and photo pattern. As such, an optional protective layer (not shown) may be used to prevent oxidation of the NiV material. For example, a thin layer of aluminum may be deposited using sputter deposition. The aluminum layer may be removed prior to plating metals onto the NiV surface.

Optionally, following the deposition of NiV layer 804, or removal of the aluminum if used to prevent oxidation, a thin layer of palladium metal catalyst (not shown) may be deposited atop the NiV layer 804 via immersion plating methods. Next, a layer 806 of palladium-phosphorous (Pd—P) alloy with P in the range of 0.1-10% by weight, and more preferably of 0.1-5%, is deposited via electroless plating methods (either on the palladium metal catalyst, if used, or atop the NiV layer, if the catalyst is not used). The thickness of the Pd—P deposit is preferably between 0.1-5 microns.

Subsequently, a layer 808 of gold is plated via immersion plating methods. The thickness of the gold layer may be in the range of 0.02-3.0 microns, and preferably between 0.05-0.10 microns.

In this embodiment, the NiV and Pd—P layers 804 and 806 can act as either barrier and/or solderable layers depending on the thickness of the layers. The gold layer 808 acts as a protective layer.

### EXAMPLE 7

A UBM structure, similar to the structure 800, is formed following the steps of Example 6, except a layer of aluminum, which acts as the adhesion layer, replaces the titanium in layer 802 in the initial metal deposition step above.

### EXAMPLE 8

A UBM structure, similar to the structure 800, is formed following the steps of Examples 6 or 7 above except that a layer of tungsten replaces the NiV layer 804 in the barrier metal deposition step.

### EXAMPLE 9

A UBM structure, similar to the structure 800, is formed following the steps of Example 6, except that titanium is used for both adhesion layer 802 and barrier layer 804.

### EXAMPLE 10

A UBM structure 900, illustrated in FIG. 7, is formed using the initial metal deposition, barrier metal deposition, optional protective layer deposition, and gold layer deposition steps of Example 6 above. A layer of gold 808 is deposited via immersion plating methods atop the NiV layer 804 (note that the Pd—P layer 806 is omitted in this example). The thickness of the Au layer 808 is in the range of 0.02-3.0 microns, and preferably between 1-2 microns. In this embodiment, the NiV layer 804 acts as a barrier and/or solderable layer. The Au layer 808 acts as a protective or solderable/bondable layer depending on the thickness of the layer.

### EXAMPLE 11

A UBM structure 1000, illustrated in FIG. 8, is formed initially following the initial metal deposition step of Example 6, wherein a layer 802 of titanium is deposited upon the metallization layer 202. Thereafter, a layer 1002 of tungsten (W) is deposited via sputtering methods upon the titanium layer 802. After the W layer 1002 is deposited, a layer 1004 of nickel-phosphorous (Ni—P) having P in the range of 1-16%, and preferably between 7-9%, is deposited via electroless plating methods. The thickness of Ni—P layer 1004 is in the range of 0.1-50 microns, and preferably between 1-5 microns. Following the Ni—P deposition, a layer 808 of gold is plated via immersion plating methods. The thickness of the gold layer 808 is in the range of 0.02-3.0 microns, and preferably between 0.02-0.10 microns.

### EXAMPLE 12

A UBM structure is formed, similarly to the UBM structure 1000 of Example 11, except that the Ni—P layer 1004 of Example 11 is replaced with a layer of sputtered NiV.

### EXAMPLE 13

A UBM structure is formed similarly to the UBM structure 1000 of Example 11, except that the W layer 1002 of Example 11 is replaced with a layer of sputtered Ti/W alloy.

### EXAMPLE 14

A UBM structure is formed similarly to the UBM structure 1000 of Example 11, except that the W layer 1002 of Example 11 is replaced with a layer of sputtered Ti/W/N alloy.

### EXAMPLE 15

A UBM structure is formed similarly to the UBM structure 1000 of Example 11, except that the W layer 1002 of Example 11 is replaced with a layer of sputtered Ti/W alloy (in the barrier metal deposition step), and the Ni—P layer 1004 is replaced with a sputtered layer of NiV alloy (in the alloy deposition step).

### EXAMPLE 16

A UBM structure is formed similarly to the UBM structure 1000 of Example 11, except that the W layer 1002 of Example 11 is replaced with a layer of sputtered Ti/W/N alloy (in the barrier metal deposition step), and the Ni—P layer 1004 is replaced with a sputtered layer of NiV alloy (in the alloy deposition step).

### EXAMPLE 17

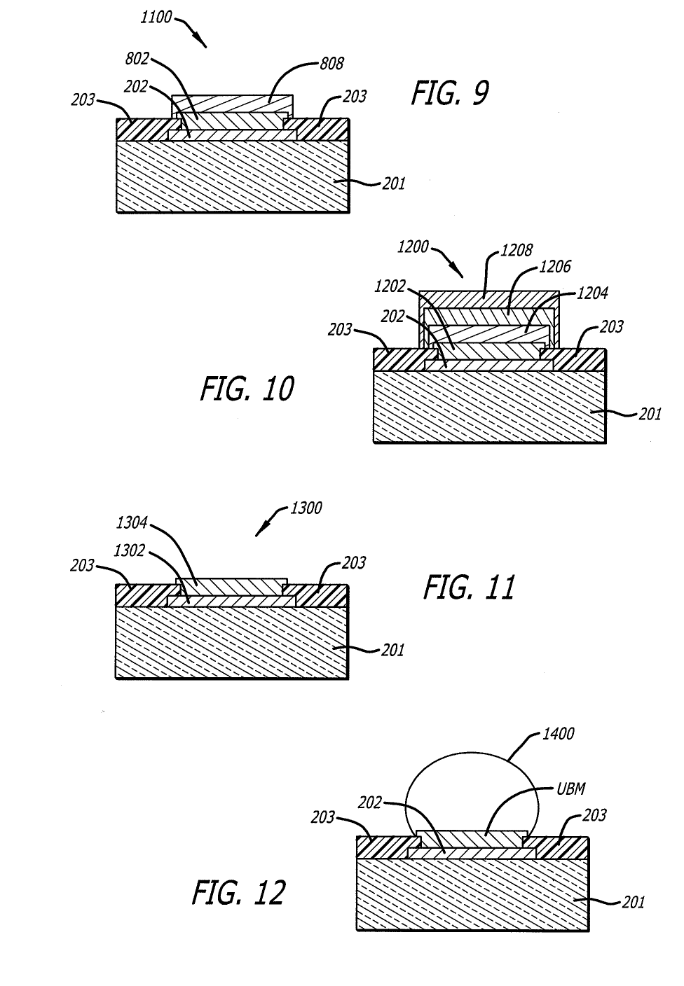

A UBM structure 1100, illustrated in FIG. 9, is formed by initially depositing a layer of titanium 802 upon the device metallization 202, then depositing a layer 808 of gold via electroless or immersion plating. The thickness of this Au layer 808 may be, for example, in the range of about 0.02-3 microns. In this embodiment, the titanium layer 802 acts as both an adhesion and barrier layer. The gold layer 808 acts as a protective or solderable layer, depending on the thickness of the layer.

The individual sputtered metal/alloy layers in Examples 6-17 also can range, for example, in thickness from about 0.01-1 microns depending on the desired function. Desirably, the thickness should be sufficient to form a good barrier while at the same time ensuring that stress-related peeling or cracking is minimized.

As an alternative to the electroless and immersion plating methods described in the above examples, the plating can be performed via electrolytic methods. The electroless and or immersion plating would be done by electrolytic plating. For the electroless plated alloys, only the metal component of the alloy (e.g., Ni or Pd) is plated (i.e., plated without the phosphorous alloying element). No catalyst layers are needed with the electrolytic plating method. The sputtered Ti and W layers described in Examples 6-17 can also alternatively be plated using electrolytic methods.

### EXAMPLE 18

A UBM structure 1200, illustrated in FIG. 10, is formed on the surface of the device copper or aluminum metallization 202 via sputtering. Specifically, the first layer 1202 of sputtered metal is a TiW alloy with thickness in the range of about 50-10,000 angstroms. The second layer 1204 of sputtered metal is a Ti/W/N alloy with a thickness in the range of about 50-10,000 angstroms. The third layer 1206 of sputtered metal is a TiW alloy with thickness in the range of about 50-10,000 angstroms. The fourth layer 1208 of sputtered metal is Au with thickness in the range of about 50-10,000 angstroms.

### EXAMPLE 19

The UBM structure here is similar to Example 18, except the first layer TiW alloy 1202 of UBM structure 1200 is not used.

### EXAMPLE 20

The UBM structure here is similar to Example 18, except the third layer TiW alloy 1206 of UBM structure 1200 is not used.

### EXAMPLE 21

The UBM structure here is similar to Example 18, except the first and third layers (1202, 1206) of the TiW alloy of UBM structure 1200 are not used.

### EXAMPLE 22

The UBM structure here is similar to Example 18, except the second and third layers (1204, 1206) of the Ti/W/N and TiW alloys of UBM structure 1200 are not used.

### EXAMPLE 23

As illustrated in FIG. 11, a UBM structure 1300 is formed with a device metallization layer 1302 of gold. In forming structure 1300, a layer 1304 of gold is sputtered on top of device metallization layer 1302. The thickness of layer 1304 is, for example, in the range of about 50-10,000 angstroms.

### EXAMPLE 24

A UBM structure similar to UBM structure 1300 is formed in which no metal is sputtered on top of the device metallization layer 1302. The device metallization layer 1302 itself acts as the UBM structure, upon which a solder bump is later formed.

### EXAMPLE 25

A UBM structure similar to UBM structure 1300 of Example 23 is formed, but after layer 1304 is sputtered, an additional layer of gold (not shown) is plated on top of layer 1304 by, for example, electroless, immersion, or electrolytic methods to a thickness of between about 0.5-150 microns.

### Formation of the Solder Bump

After formation of the UBM structure, in accordance with one of the examples described above or with other appropriate fabrication approaches, an interconnect bump (e.g., a solder bump) is formed on the UBM structure. The solder bump is formed at the wafer level and attached to the UBM structure through, for example, reflow or plating methods. A general illustration of solder bump structure 1400 is provided in FIG. 12. Though the following examples describe the formation of the solder bump 1402 using solder paste printing and plating methods, pre-formed solder sphere deposition and other appropriate methods may be used to form the solder bumps on the UBM structure.

### 1. Solder Bump Formed with Printed Paste Deposition

In a first embodiment of the solder bump structure 1400, solder paste made from a suitable high temperature alloy is deposited via printing methods through openings in an in-situ or separate stencil and onto the UBM structure. The deposited solder paste is then reflowed to form the solder bump 1402. The resulting solder bump height after reflow is, for example, about 1-500 microns. During reflow, metallic bonds are formed between the solder bump and the underlying UBM structure. Suitable solder paste alloys include the following examples: eutectic Au/Sn (80Au20Sn with 280° C. eutectic), eutectic lead/silver (97.5Pb/2.5Ag with 303° C. eutectic), eutectic lead/silver/tin (97.5Pb/1.5Ag/1Sn with 309° C. eutectic), high lead/tin (95Pb/5Sn, 314° C. melting point), eutectic gold/germanium (88Au12Ge with 356° C. eutectic), eutectic gold/silicon (97Au3Si with 363° C. eutectic), eutectic zinc/aluminum (94Zn/6Al with 381° C. eutectic), and eutectic germanium/aluminum (55Ge/45Al with 424° C. eutectic).

### 2. Solder Bump Formed with Plated Deposition

In a second embodiment of the bump structure, a suitable material may be plated onto the aluminum or copper device, silicon submount, or other substrate metallization surface or onto, for example, any of the UBM structures described in Examples 1-10 to form a bump for interconnects. In this embodiment the material is plated to a thickness between about 1 and 500 microns. The plating may be performed via electroless, immersion, or electrolytic methods depending on the type of metal and the thickness to be plated. The bump may be applied to the device or the substrate. The device may be attached to the substrate with thermo-sonic or thermo-compression die attach techniques, or by reflow techniques if applicable. Suitable plating metals or alloys that can be used in this embodiment include the following examples: gold (Au), silver (Ag), palladium (Pd), eutectic lead/silver (97.5Pb/2.5Ag), high lead/tin (95Pb/5Sn), eutectic zinc/aluminum (94Zn/6Al), and eutectic 80Au20Sn.

In a third embodiment of the solder bump structure, the bump material is applied as in the second embodiment above. In this embodiment, the device, silicon submount, or other substrate is attached to the mating substrate with reflow techniques through the use of a solder alloy. Using this method, a solder alloy material with a melting point lower than the bump material is applied on either the bump surface or the mating substrate attach surface. This material acts as a lower melting point surface (as compared to the solder bump) to which both the bump and mating substrate attach surface will bond upon reflow. This will allow a reliable connection to be formed at a lower reflow temperature than would be necessary to reflow the bump. Suitable solder alloy materials that can be used in this embodiment include the following examples: eutectic lead/silver (97.5Pb/2.5Ag with 303° C. eutectic), eutectic lead/silver/tin (97.5Pb/1.5Ag/1Sn with 309° C. eutectic), high lead/tin (95Pb/5Sn, 314° C. melting point), eutectic gold/germanium (88Au12Ge with 356° C. eutectic), eutectic gold/silicon (97Au3Si with 363° C. eutectic), eutectic zinc/aluminum (94Zn/6Al with 381° C. eutectic), eutectic germanium/aluminum (55Ge/45Al with 424° C. eutectic), and eutectic gold/tin (80Au20Sn with 280° C. eutectic).

### 3. Solder Bump Formed with Pre-Formed Solder Spheres

Pre-formed solder spheres made with any of the bump materials already discussed can also be deposited on any of the UBM structures discussed above to form the high-temperature interconnect structure.

### CONCLUSION

Examples of applications for the above described interconnect bump structures may include, depending on the specific embodiment, the following: electronic modules containing one or more interconnected power amplification stages; high density, multiple-level interconnected integrated circuit electronic devices on a BGA package requiring a high thermal dissipation requirement; multi-level circuit boards containing one or more layers of interconnected, embedded electronic circuits; and light-emitting diode devices that output a large output power level and/or dissipate a large power level under normal operating conditions. The interconnect bump structures described above typically may be used in a wide variety of electronic packaging applications, including, for example, ball grid array (BGA), chip scale package (CSP) and flip chip structures.

While the present disclosure has been presented with respect to exemplary embodiments, such description is for illustrative purposes only, and is not to be construed as limiting the scope of the invention. Various modifications and changes may be made to the described embodiments by those skilled in the art without departing from the true spirit and scope of the invention as set forth in the claims. The invention is to be determined by the following claims.

1. An interconnect bump structure comprising:
an alloy layer of a material selected from the group consisting of Ni-P and Pd-P;
a gold layer overlying the alloy layer; and
a bump, overlying the gold layer, of a material selected from the group consisting of: PbSbGa, PbSb, AuGe, AuSi, AuSn, ZnAl, CdAg, GeAl, Au, Ag, Pd, Pb, Ge, Sn, Si, Zn, Al, and combinations thereof.

2. The structure of claim 1 wherein the bump is a layer of solder material.

3. The structure of claim 1 wherein the bump is a substantially pure metal interconnect bump.

4. The structure of claim 1 wherein the bump is a solder bump.

5. The structure of claim 1 further comprising a Pd catalyst layer disposed beneath the alloy layer.

6. The structure of claim 1 wherein the alloy layer is Ni-P and further comprising a Pd-P layer disposed between the alloy layer and the gold layer.

7. The structure of claim 6 further comprising a Pd catalyst layer disposed between the alloy layer and the Pd-P layer.

8. The structure of claim 1 wherein the alloy layer is a first Ni-P layer, and further comprising a second Ni-P layer disposed between the first Ni-P layer and the gold layer, wherein the second Ni-P layer has a weight percentage of P that is less than the weight percentage of P of the first Ni-P layer.

9. The structure of claim 1 wherein the bump material is 98Pb1.2SbO.8Ga, 98Pb2Sb, 98.5Pbl.5Sb, 88Aul2Ge, 97Au3Si, 94Zn6A1, 95Cd5Ag, 55Ge45A1, or 80Au20Sn.

10. (canceled)

11. An interconnect bump structure comprising:
a first metal layer of a material selected from the group consisting of: Ti, Al, and TiW;
a second metal layer, overlying the first metal layer, of a material selected from the group consisting of: Au and Ag; and
a bump, overlying the second metal layer, of a material selected from the group consisting of: PbSbGa, PbSb, AuGe, AuSi, AuSn, ZnAl, CdAg, GeAl, Au, Ag, Pd, Pb, Ge, Sn, Si, Zn, Al, and combinations thereof.

12. The structure of claim 11 further comprising a third metal layer, disposed between the first metal layer and the second metal layer, of a material selected from the group consisting of: NiV, W, Ti, TiW, Ti/W/N, and Pt.

13. The structure of claim 12 further comprising an alloy layer, disposed between the second metal layer and the third metal layer, of a material selected from the group consisting of: Pd-P, Ni-P, NiV, and TiW.

14. The structure of claim 11 further comprising an alloy layer, disposed between the first metal layer and the second metal layer, of a material selected from the group consisting of: Pd-P, Ni-P, NiV, and TiW.

15. The structure of claim 11 wherein the bump material is 98Pb1.2SbO.8Ga, 98Pb2Sb, 98.5Pbl.5Sb, 88Aul2Ge, 97Au3Si, 94Zn6A1, 95Cd5Ag, 55Ge45Al, or 80Au20Sn.

16. An interconnect bump structure comprising:
a first metal layer of a material selected from the group consisting of: NiV, W, Ti, TiW, Ti/W/N, and Pt;
a second metal layer, overlying the first metal layer, of a material selected from the group consisting of: Au and Ag; and
a bump, overlying the second metal layer, of a material selected from the group consisting of: PbSbGa, PbSb, AuGe, AuSi, AuSn, ZnAl, CdAg, GeAl, Au, Ag, Pd, Pb, Ge, Sn, Si, Zn, Al, and combinations thereof.

17. The structure of claim 16 further comprising an alloy layer, disposed between the first metal layer and the second metal layer, of a material selected from the group consisting of: Pd-P, Ni-P, NiV, and TiW.

18. The structure of claim 16 wherein the bump material is 98Pb1.2SbO.8Ga, 98Pb2Sb, 98.5Pbl.5Sb, 88Aul2Ge, 97Au3Si, 94Zn6Al, 95Cd5Ag, 55Ge45Al, or 80Au20Sn.

19. An integrated circuit device comprising:
a substrate;
a gold contact pad above the substrate; and
a bump overlying the gold contact pad, wherein the bump is: (i) operable at temperatures above 250 degrees Celsius; and (ii) of a material selected from the group consisting of: PbSbGa, PbSb, AuGe, AuSi, AuSn, ZnAl, CdAg, GeAl, Au, Ag, Pd, Pb, Ge, Sn, Si, Zn, Al, and combinations thereof.

20. The device of claim 19 further comprising a gold layer disposed between the gold contact pad and the bump.

21. The device of claim 20 wherein the gold layer is a first gold layer, and further comprising a second gold layer disposed between the first gold layer and the bump.

22. The device of claim 19 wherein the bump material is 98Pbl.2SbO.8Ga, 98Pb2Sb, 98.5Pbl.5Sb, 88Aul2Ge, 97Au3Si, 94Zn6Al, 95Cd5Ag, 55Ge45Al, or 80Au20Sn.

23. An LED device comprising an interconnect bump structure, wherein the interconnect bump structure comprises:
an alloy layer of Ni-P or Pd-P;
a bump, overlying the alloy layer, of a material selected from the group consisting of PbSbGa, PbSb, AuGe, AuSi, AuSn, ZnAl, CdAg, GeAl, Au, Ag, Pd, Pb, Ge, Sn, Si, Zn, Al, and combinations thereof; and
wherein the interconnect bump structure is operable at temperatures above 250 degrees Celsius.

24. The device of claim 23 further comprising a gold layer disposed between the alloy layer and the bump.

25. The device of claim 24 wherein the gold layer has a thickness of about 0.02 to 3.0 microns.

26. The device of claim 23 further comprising a contact pad, underlying the interconnect bump structure, comprising Al or Cu.

27-44. (canceled)
